(19) United States
(12) Patent Application Publication
(10) Pub. No.: US 2012/0221923 A1
(43) Pub. Date: Aug. 30, 2012

(54) MEMORY SYSTEM AND MEMORY MODULE CONTROL METHOD

(75) Inventor: Shusaku UCHIBORI, Tokyo (JP)

(73) Assignee: NEC Computertechno, Ltd., Yamanashi (JP)

(21) Appl. No.: 13/403,162

(22) Filed: Feb. 23, 2012

(30) Foreign Application Priority Data
Feb. 25, 2011 (JP) 2011-039210

(51) Int. Cl. H03M 13/05; G06F 11/10

(52) U.S. Cl. 714/763; 714/E11.034

(57) ABSTRACT

A memory system includes a memory module of first to eighth semiconductor memories of an n-bit input/output type; and a memory control unit configured to generate three n-bit error detection and correction codes based on four n-bit data received from an external system, respectively store the four n-bit data in the first to fourth semiconductor memories, and respectively store the three n-bit error detection and correction code in the fifth to seventh semiconductor memories. When reading the four n-bit data stored in the first to fourth semiconductor memories, the memory control unit executes error detection to every two of the four n-bit data read from the first to fourth semiconductor memories based on the three n-bit error detection and correction code stored in the fifth to seventh semiconductor memories and executes error correction to one n-bit data related to an error, of the four n-bit data.

### CROSS REFERENCE

This patent application claims a priority on convention based on Japanese Patent Application No. 2011-039210. The disclosure thereof is incorporated herein by reference.

### TECHNICAL FIELD

The present invention is related to a memory system and a memory module control method.

### RELATED ART

In a mission critical system such as a server, protection through ECC (Error Check and Correction) is implemented for a data error measure of DIMM (Dual Inline Memory Module). FIG. 1 is a diagram showing a memory system 100 provided with a general DIMM 110 with ECC function. Referring to FIG. 1, the memory system 100 is provided with a DIMM 110, a memory control unit 120 and a general DIMM interface section 130. The memory system 100 is connected with an external unit 200 through a system interface section 300 and carries out transmission and reception of data.

The DIMM 110 contains nine DRAM (Dynamic Random Access Memory) 111 and each DRAM 111 is of an 8-bit input/output type. The DIMM 110 is configured by adding one 1-byte DRAM 111 for ECC to the general 8-byte DIMM of eight 1-byte DRAMs 111. The memory control unit 120 is provided with a detecting section 121 and a DIMM interface section 122.

An operation of the memory system 100 will be described. First, a data write operation into the DIMM 110 will be described. The external unit 200 outputs the 8-byte data and a write request to the memory system 100 through the system interface section 300. The detecting section 121 generates the 1-byte error detection and correction code based on the 8-byte data when receiving the write request. The detecting section 121 supplies the 8-byte data and the 1-byte error detection and correction code to the DIMM interface section 122. The DIMM interface section 122 stores the 8-byte data and the 1-byte error detection and correction code in the memory module 110 through the general DIMM interface section 130 when receiving the 8-byte data, the 1-byte error detection and correction code and the write request from the detecting section 121. In detail, the DIMM interface section 122 respectively stores the 8 bytes of data in the eight DRAMs 111, and stores the 1-byte error detection and correction code in the remaining DRAM 111.

Next, a data read operation from the DIMM 110 will be described. The external unit 200 supplies a data read request to the memory system 100 through the system interface section 300. The detecting section 121 supplies the data read request to the DIMM interface section 122. When receiving the data read request from the detecting section 121, the DIMM interface section 122 reads the 8-byte data from the eight DRAMs 111 and the 1-byte error detection and correction code from the remaining DRAM 111. The DIMM interface section 122 supplies the 8-byte data and the 1-byte error detection and correction code to the detecting section 121. The detecting section 121 executes 1-bit correction or 2-bit error detection based on the 1-byte error detection and correction code.

The technique of error correction and detection is disclosed in Patent Literatures 1 to 4. In Patent Literature 1, a memory unit is disclosed in which a general DIMM product can be used and which can correct data even in case of a chip trouble. This memory unit has a section for specifying the optional number of bytes as ECC, and data and error correcting code exist on an identical word on the memory.

In Patent Literature 2, a memory data input/output control method of EEPROM (Electrically Erasable Programmable Read-Only Memory) is disclosed. In the memory data input/output control method, write data is composed true data for a half of memory data and inversion data of the true data as parity data for the remaining half.

In Patent Literature 3, a memory system is disclosed in which error detection by chip kill is executable without necessitating an expensive custom ASIC chip and an additional memory module in a low end server system

In Patent Literature 4, a storage circuit module is disclosed in which it is possible to execute an ECC error correction and detection by using a memory such as existing SIMM (Single In-line Memory Module). The storage circuit module is provided with a data storage section, an ECC memory section, a correction code generating section which generates an error correcting code, and a correcting and detecting section which carries out error correction and detection using the error correcting code stored in the ECC memory section. The ECC memory section is composed of storage elements, each of which does not have an error correction function.

### CITATION LIST

[Patent Literature 1]: JP 2009-245218A
[Patent Literature 2]: JP H02-122349A
[Patent Literature 3]: JP 2001-142789A
[Patent Literature 4]: JP H10-111839A

### SUMMARY OF THE INVENTION

Because it is SECDED (1-bit correction and 2-bit detection) that can be realized by 1-byte ECC code (error detection and correction code), the above-mentioned memory system 100 cannot execute S8ECD8ED (1-byte correction and 2-byte detection). In other words, in the above memory system 100, it means that a failure of one DRAM 111 cannot be corrected. The error detection and correction code necessary for S8ECD8ED is of 3-byte. Therefore, when trying to realize this in the memory system 100, three sheets of a general DIMM 110 with ECC function must be used at a same time. FIG. 2 is a diagram showing a memory system 101 which is provided with the three sheets of a general DIMMs 110 with ECC function. It should be noted that because each section of the memory system 101 in FIG. 2 is same as the memory system 100 of FIG. 1, the detailed description is omitted. In the memory system 101 of FIG. 2, the three sheets of the general DIMM 110 with ECC function which is expensive compared with the general DIMM with no ECC function are required, and the general DIMM interface 130 becomes necessary 3 times so that being expensive. Also, the design becomes difficult.

The technique is required to realize an advanced error correction only by one sheet of a general memory module and provide high reliability in a memory system.

A memory system includes a memory module of first to eighth semiconductor memories of an n-bit input/output type; and a memory control unit configured to generate three n-bit error detection and correction code based on four n-bit data received from an external system, respectively store the four n-bit data in the first to fourth semiconductor memories, and respectively store the three n-bit error detection and correction code in the fifth to seventh semiconductor memories. When reading the four n-bit data stored in the first to fourth semiconductor memories, the memory control unit executes error detection to every two of the four n-bit data read from the first to fourth semiconductor memories based on the three n-bit error detection and correction code stored in the fifth to seventh semiconductor memories and executes error correction to one n-bit data related to an error, of the four n-bit data based on the three n-bit error detection and correction code.

A memory module control method is achieved by writing four n-bit data received from an external system in a memory module comprising first to eighth semiconductor memories; and by reading the four n-bit data from the memory module in response to on a request from the external system. The writing is attained by receiving the four n-bit data from the external system; by generating three n-bit error detection and correction code based on the four n-bit data; by storing the four n-bit data in the first to fourth semiconductor memories, respectively; and by storing the three n-bit error detection and correction code in the fifth to seventh semiconductor memories, respectively. The reading is attained by reading the four n-bit data from the first to fourth semiconductor memory in response to the request from the external system, respectively; by reading the three n-bit error detection and correction code from the fifth to seventh semiconductor memories, respectively; by executing error detection to every two of the four n-bit data read from the first to fourth semiconductor memories based on the three n-bit error detection and correction code read from the fifth to seventh semiconductor memories; and by executing error correction to one n-bit data related to an error, of the four n-bit data based on the three n-bit error detection and correction code, when the error is detected in the four n-bit data.

The memory system realizes the advanced error correction only by one sheet of a general memory module and can attain high reliability.

### BRIEF DESCRIPTION OF THE DRAWINGS

FIG. 1 is a diagram showing a conventional memory system 100 provided with a general DIMM 110 with ECC function;

FIG. 2 is a diagram showing a conventional memory system 101 provided with three sheets of the general DIMM 110 with ECC function;

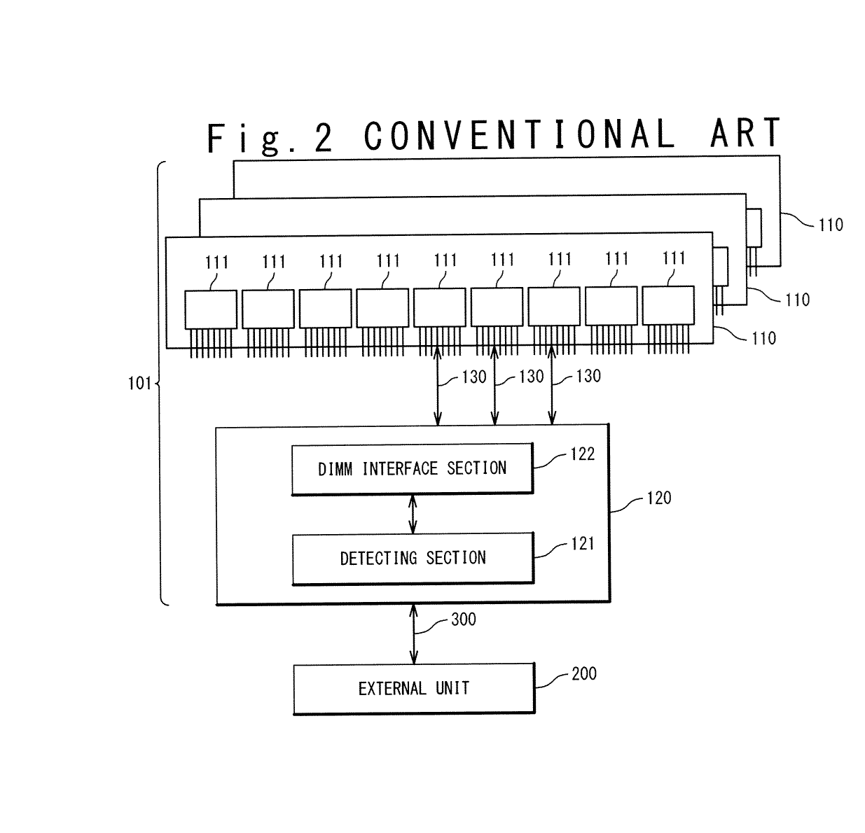

FIG. 3 is a diagram showing a memory system 1 according to a first exemplary embodiment of the present invention;

FIG. 4 is a flow chart showing a data write operation of the memory system 1 according to the first exemplary embodiment of the present invention;

FIG. 5 is a flow chart showing a data read operation of the memory system 1 according to the first exemplary embodiment of the present invention;

FIG. 6 is a diagram showing a memory system 1a according to a second exemplary embodiment according to the present invention; and

FIG. 7 is a diagram showing a memory system 1b according to a third exemplary embodiment of the present invention.

### DESCRIPTION OF EXEMPLARY EMBODIMENTS

Hereinafter, a memory system according to the present invention will be described with reference to the attached drawings.

### First Exemplary Embodiment

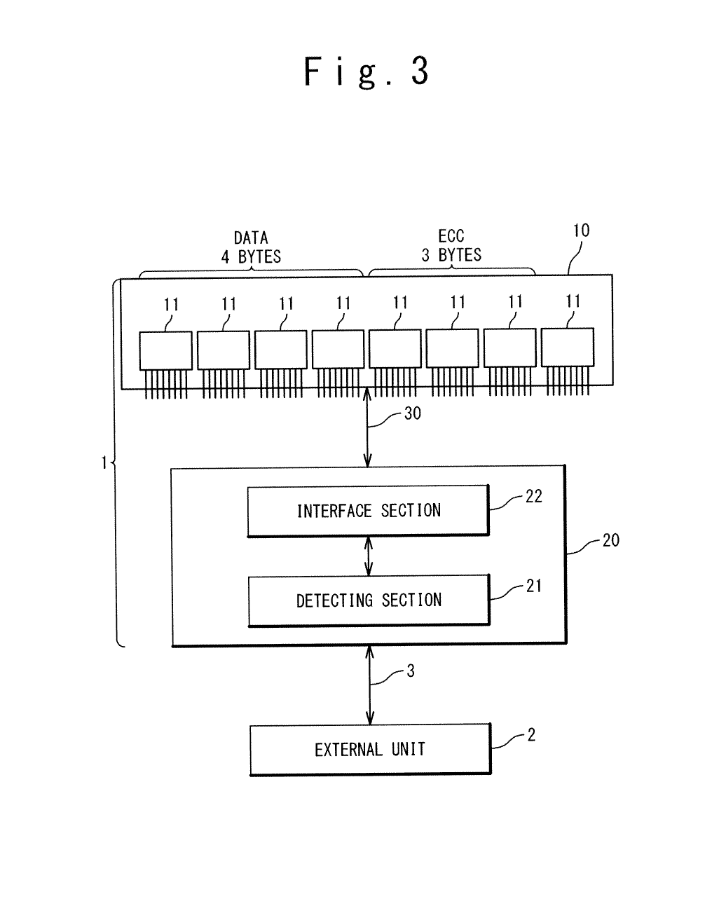

A first exemplary embodiment according to the present invention will be described. FIG. 3 is a diagram showing a memory system 1 according to the first exemplary embodiment of the present invention. Referring to FIG. 3, the memory system 1 is provided with a memory module 10, a memory control unit 20 and an interface section 30. The memory system 1 is connected with an external unit 2 through a system interface 3.

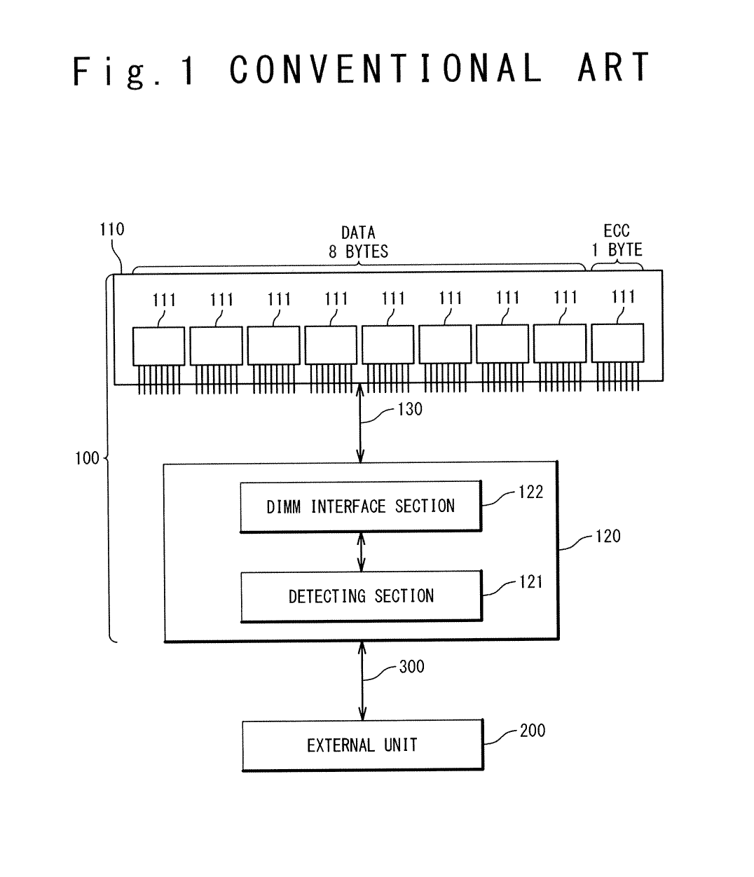

The memory module 10 is a general memory module and has at least eight semiconductor memories 11 which are mounted onto a printed board. As the memory module 10, DIMM (Dual Inline Memory Module) and SIMM (Single In-line Memory Module) are exemplified. Because it is desirable that the memory module 10 of the present invention is of a general type, it is ideal that the memory module 10 has the eight semiconductor memories 11. However, the DIMM 110 shown in FIG. 1 may be used, and the memory module 10 may have nine semiconductor memories 11.

The semiconductor memory 11 is a chip of a semiconductor device in which data can be stored, and DRAM (Dynamic Random Access Memory) and SRAM (Static Random Access Memory) are exemplified. Referring to FIG. 3, the semiconductor memory 11 is of an 8-bit input/output type but may be a 4-bit input/output type. In the present exemplary embodiment, a case that the semiconductor memory 11 is of the 8-bit input/output type will be described as an example.

When writing data of 4×8 bits (4 bytes) received from the external unit 2 into the memory module 10, the memory control unit 20 generates an error detection and correction code of 3×8 bits (3 bytes) based on the data of 4×8 bits (4 bytes). It should be noted that the 3-byte error detection and correction code is a code for realizing S8ECD8ED (1-byte correction and 2-byte detection). The memory control unit 20 stores the 4-byte data in the four semiconductor memories 11 one byte by one byte, and the 3-byte error detection and correction code in the remaining three semiconductor memories 11 one byte by one byte. Also, when reading the 4-byte data retained in the four semiconductor memories 11 of the memory module 10, the memory control unit 20 executes a 1-byte error correction or a 2-byte error detection based on the 3-byte error detection and correction code retained in the three semiconductor memories 11. In other words, the memory control unit 20 executes the error correction to one semiconductor memory 11 of the four semiconductor memories 11 or the error detection to two semiconductor memories 11 thereof.

The details of the memory control unit 20 will be described. The memory control unit 20 is provided with a detecting section 21 and an interface section 22. At the time of writing data, that is, when receiving 4-bytes data and a write request from the external unit 2 through the system interface section 3, the detecting section 21 generates the 3-byte error detection and correction code based on the 4-byte data. The detecting section 21 supplies the 4-byte data, the 3-byte error detection and correction code and the write request to the interface section 22.

Also, at the time of reading data, that is, when receiving the 4-byte data and the 3-byte error detection and correction code from the interface section 22, the detecting section 21 executes the error detection to every two of the four semiconductor memories 11 based on the 3-byte error detection and correction code and the error correction to one of the four semiconductor memories 11 based on the 3-byte error detection and correction code. In detail, the detecting section 21 determines whether or not there is an error in the data read from the four semiconductor memories 11 for every two bytes based on the 3-byte error detection and correction code. When determining that there is not any error, the detecting section 21 supplies the 4-byte read data to the external unit 2 through the system interface 3. On the other hand, when determining that there is any error, the detecting section 21 executes the error correction to one semiconductor memory 11 of the four semiconductor memories 11 based on the 3-byte error detection and correction code. In this case, when executing the error correction to one semiconductor memory 11, the detecting section 21 supplies 1-byte corrected data to the interface section 22 in order to store it in the semiconductor memory 11 storing the error data. Then, the detecting section 21 supplies the 4-byte data which contains the 1-byte corrected data, to the external unit 2 through the system interface 3. On the other hand, when executing the error detection of the two semiconductor memories 11, the detecting section 21 informs a failure to the external unit 2.

At the time of writing data, that is, when receiving the 4-byte data, the 3-byte error detection and correction code and a write request from the detecting section 21, the interface section 22 stores these data in the memory module 10 through the interface section 30 in response to the write request. In detail, the interface section 22 stores the 4-byte data in the four semiconductor memories 11 one byte by one byte, and 3-byte of the error detection and correction code in the remaining three semiconductor memories 11 one byte by one byte.

Also, at the time of reading data, that is, when receiving a read request from the detecting section 21, the interface section 22 reads the 4-byte data from the four data semiconductor memories 11 and the 3-byte error detection and correction code from the three semiconductor memories 11. The interface section 22 supplies the 4-byte data and the 3-byte error detection and correction code to the detecting section 21.

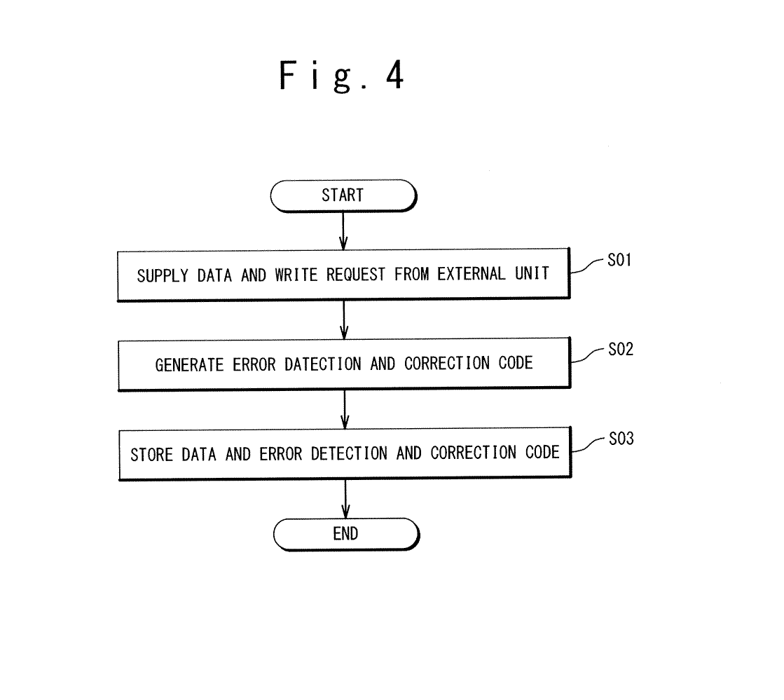

An operation the memory system 1 of the first exemplary embodiment will be described. FIG. 4 is a flow chart showing a data write operation of the memory system 1 according to the first exemplary embodiment of the present invention. Referring to FIG. 4, the data write operation in the first exemplary embodiment of the present invention will be described.

### (Data Write Operation)

### Step S01:

The external unit 2 supplies the 4-byte data and the write request to the memory system 1 through the system interface section 3.

### Step S02:

When receiving the 4-byte data and a write request, the detecting section 21 generates the 3-byte error detection and correction code based on the 4-byte data. The detecting section 21 supplies the 4-byte data, the 3-byte error detection and correction code and the write request to the interface section 2.

### Step S03:

When receiving the 4-byte data, the 3-byte error detection and correction code and the write request from the detecting section 21, the interface section 22 stores these data in the memory module 10 through the interface section 30 in response to the write request. In detail, the interface section 22 stores the 4-bytes data in the four semiconductor memories 11 one byte by one byte and the 3-byte error detection and correction code in the remaining three semiconductor memories 11 one byte by one byte.

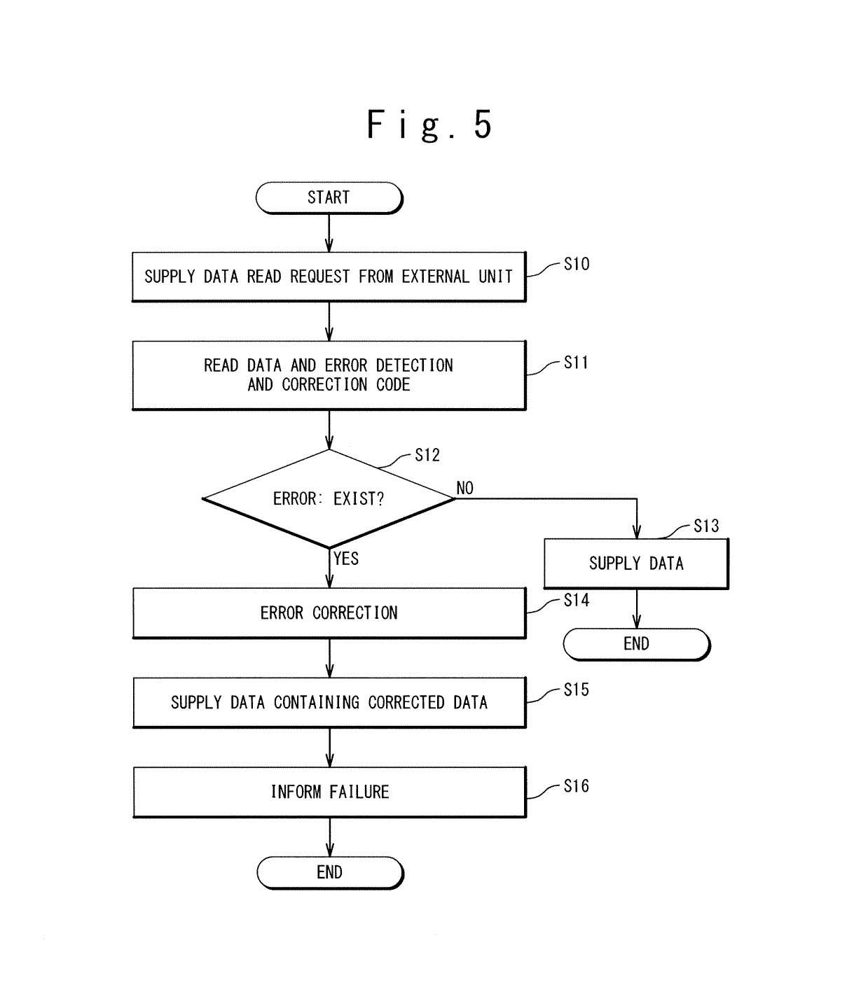

FIG. 5 is a flow chart showing a data read operation of the memory system 1 according to the first exemplary embodiment of the present invention. Referring to FIG. 5, the data read operation in the first exemplary embodiment of the present invention will be described.

### (Data Read Operation)

### Step S10:

The external unit 2 supplies a data read request to the memory system 1 through the system interface section 3.

### Step S11:

The detecting section 21 supplies the read request to the interface section 22. When receiving the read request from the detecting section 21, the interface section 22 reads the 4-byte data from the four semiconductor memories 11 and the 3-byte error detection and correction code from the three semiconductor memories 11. The interface section 22 supplies the 4-byte data and the 3-byte error detection and correction code to the detecting section

### Step S12:

The detecting section receives the 4-byte data and the 3-byte error detection and correction code from the interface section 22. The detecting section 21 determines whether or not there is an error in the 4-byte data read from the four semiconductor memories 11, based on the 3-byte error detection and correction code.

### Step S13:

When determining at the step S12 that there is no error, the detecting section 21 supplies the 4-byte data to the external unit 2 through the system interface 3.

### Step S14:

When determining at the step S12 that there is any error, the detecting section 21 executes the error correction to the 4-byte data based on the 3-byte error detection and correction code.

Step S15:

When executing the error correction to 1-byte data of the 4-byte data at the step S14, the detecting section 21 supplies the 1-byte corrected data to the interface section 22 such that the 1-byte corrected data is stored into the semiconductor memory 11 storing the error data. Then, the detecting section 21 supplies the 4-byte data which contains the 1-byte corrected data, to the external unit 2 through the system interface 3.

### Step S16:

When the error is detected at the step S12, the detecting section 21 informs a failure to the external unit 2.

It should be noted that when each of the semiconductor memories 11 of the memory module 10 is the semiconductor memory of not the 8-bit input/output type and but the 4-bit input/output type, the error detection and correction code is a code for realizing not S8ECD8ED but S4ECD4ED (4-bit correction and 8-bit detection). In this case, the memory control unit 20 executes a 4-bit error correction or 8-bit error detection based on the 12-bit error detection and correction code. That is, in this case, the memory system 1 can execute the error correction of one of the semiconductor memories 11 in the memory module 10 or the error detection of two of the semiconductor memories 11.

As mentioned above, the memory system 1 of the present invention can realize the advanced error detection and correction, i.e. the error correction of one of the semiconductor memories 11 or the error detection of two of the semiconductor memories 11, in case of using the single memory module, resulting in attainment of high reliability. As a result, the memory system 1 of the present invention can realize a simple and cheap system without increasing the interface section 30. Especially, when using the memory module with no ECC as the general-purpose memory module 10, the memory system 1 can be realized more cheaply.

### Second Exemplary Embodiment

A second exemplary embodiment of the present invention will be described. The memory system according to the second exemplary embodiment of the present invention is same as that of the first exemplary embodiment in the basic configuration and uses one further remaining semiconductor memory 11. In detail, the memory system in the second exemplary embodiment uses the remaining semiconductor memory 11 as a spare when any of the other semiconductor memories 11 is failed.

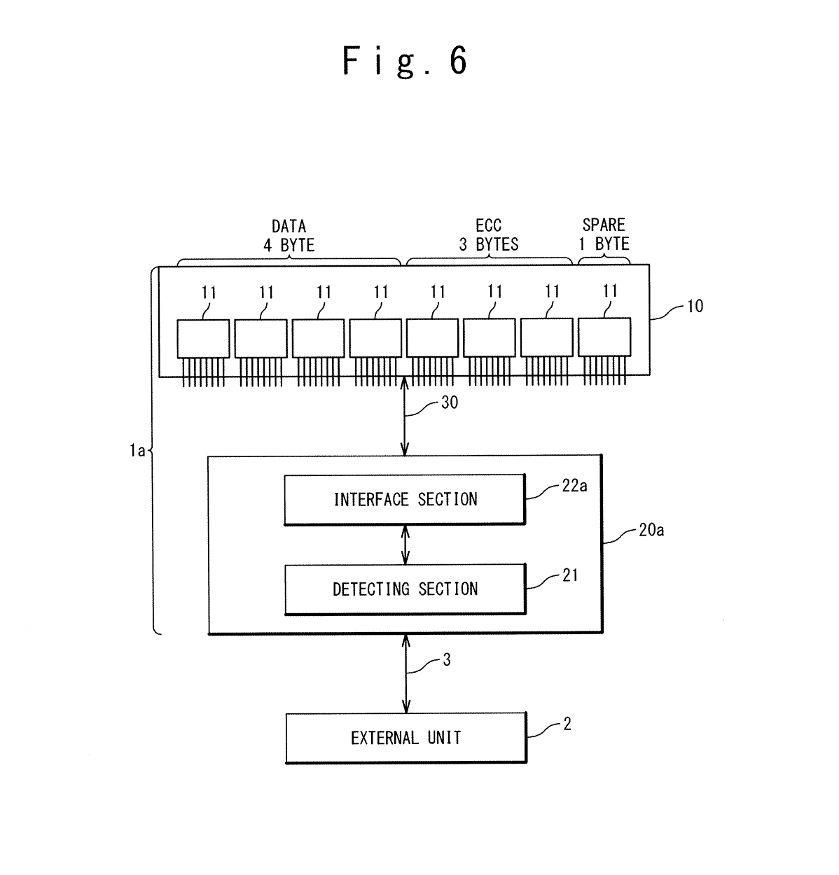

FIG. 6 is a diagram showing the memory system 1a according to the second exemplary embodiment of the present invention. Referring to FIG. 6, the memory system 1a is provided with the memory module 10, and a memory control unit 20a and the interface section 30. The memory module 10 and the interface section 30 are same as those of the memory system 1 in the first exemplary embodiment and, therefore, the description thereof is omitted.

When executing the error correction to one semiconductor memory, the memory control unit 20a stores the corrected data in the spare semiconductor memory 11 which is not used in the memory module 10. The memory control unit 20a is provided with the detecting section 21 and an interface section 22a. The detecting section 21 is same as that of the first exemplary embodiment.

Because the data write operation by the interface section 22a is same as that of the interface section 22 in the first exemplary embodiment, only the data read operation will be described. At the time of reading data, that is, when receiving a read request from the detecting section 21, the interface section 22a reads the 4-byte data from the four semiconductor memories 11 one byte by one byte and the 3-byte error detection and correction code from three semiconductor memories 11 one byte by one byte. The interface section 22a supplies the 4-byte data and the 3-byte error detection and correction code to the detecting section 21. After that, when the detecting section 21 executes the error correction to 1-byte data from one of the four semiconductor memories 11, the interface section 22a receives and retains the 1-byte corrected data from the detecting section 21. Then, the interface section 22a store the 1-byte corrected data in the spare semiconductor memory 11 in which the data and the error detection and correction code are not stored.

The data read operation of the memory system 1a according to the second exemplary embodiment of the present invention will be described. Here, referring to FIG. 5, the data read operation according to the second exemplary embodiment of the present invention will be described.

### (Data Read Operation)

### Step S10:

The external unit 2 supplies the data read request to the memory system 1a through the system interface section 3.

### Step S11:

The detecting section 21 supplies the data read request to the interface section 22a. When receiving the data read request from the detecting section 21, the interface section 22a reads the 4-byte data from the four semiconductor memories 11 one byte by one byte and the 3-byte error detection and correction code from the three semiconductor memories 11 one byte by one byte. The interface section 22a supplies the 4-byte data and the 3-byte error detection and correction code to the detecting section 21.

### Step S12:

The detecting section 21 receives the 4-byte data and the 3-byte error detection and correction code from the interface section 22a. The detecting section 21 determines whether or not there is an error in the 4-byte data read from the four semiconductor memories 11 based on the 3-byte error detection and correction code.

### Step S13:

When determining at the step S12 that there is no error, the detecting section 21 supplies the 4-byte read data to the external unit 2 through the system interface 3.

### Step S14:

When determining at the step S12 that there is an error, the detecting section 21 executes the error correction to an error byte of the 4-byte data based on the 3-byte error detection and correction code.

### Step S15:

When executing the error correction to the one semiconductor memory 11 at the step S14, the detecting section 21 supplies the 1-byte corrected data to the interface section 22a such that the corrected data is stored in the semiconductor memory 11 related to the error. Then, the detecting section 21 supplies the 4-byte data which contains the 1-byte corrected data, to the external unit 2 through the system interface 3. In this case, the interface section 22a receives and retains the 1-byte corrected data from the detecting section 21. Then, the interface section 22a stores the 1-byte corrected data in the spare semiconductor memory 11 in which the data and the error detection and correction code are not stored.

### Step S16:

When executing the error correction at the step S14, the detecting section 21 informs a failure to the external unit 2.

As mentioned above, the memory system 1a according to the second exemplary embodiment of the present invention attains the same effect as that of the first exemplary embodiment, and further uses the semiconductor memory 11 left as a spare. Thus, the memory system which is excellent in reliability can be realized. It should be noted that the memory module 10 in the second exemplary embodiment may have nine semiconductor memories 11 like the DIMM 110 of FIG. 1. In this case, because the two semiconductor memories 11 can be used as the spare (of 2 bytes), the reliability can be more improved.

### Third Exemplary Embodiment

A third exemplary embodiment of the present invention will be described. The memory system according to the third exemplary embodiment of the present invention has the same basic configuration as that of the first exemplary embodiment, and the one remaining semiconductor memory 11 is effectively used as an auxiliary semiconductor memory. The memory system in the third exemplary embodiment stores auxiliary data such as directory data received from the external unit 2 in the auxiliary semiconductor memory 11.

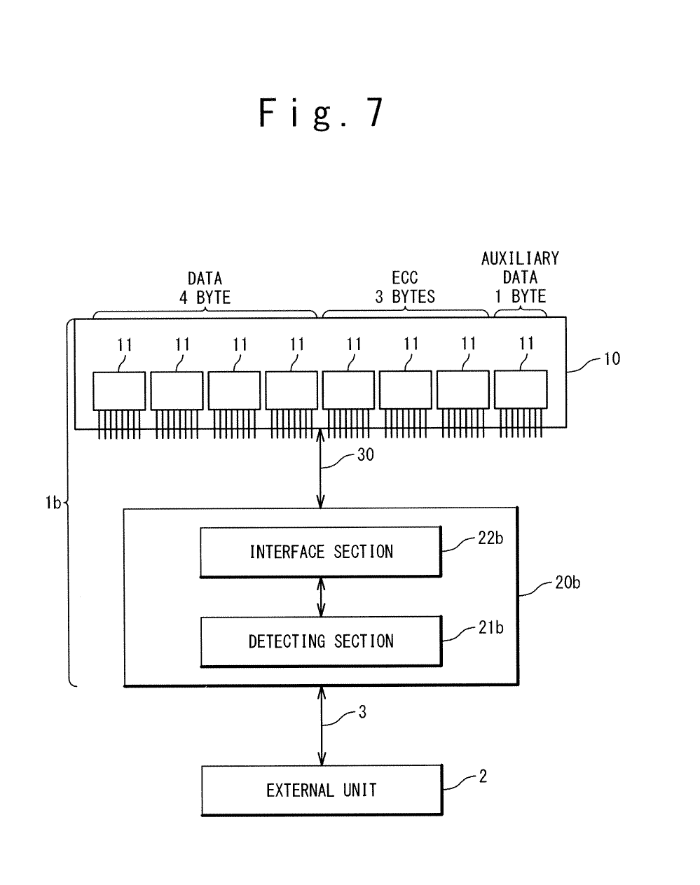

FIG. 7 is a diagram showing the memory system 1b according to the third exemplary embodiment of the present invention. Referring to FIG. 7, the memory system 1b is provided with the memory module 10, a memory control unit 20b and the interface section 30.

The memory module 10 and the interface section 30 are same as those of the memory system 1 of the first exemplary embodiment, and the description thereof is omitted.

When receiving the 4×n-bit data and the 1×n-bit auxiliary data from the external unit 2, the memory control unit 20b stores the 1×n-bit auxiliary data in the auxiliary semiconductor memory 11 which is not used in the memory module 10. The memory control unit 20b is provided with a detecting section 21b and an interface section 22b. At the time of writing data, the detecting section 21b receives the 4-byte data, the write request, and the 1-byte auxiliary data supplied from the external unit 2 through the system interface section 3. The auxiliary data is data such as directory data, and when the external unit 2 is a system which has a plurality of CPUs (Central Processing Units) which share the memory module 10, the auxiliary data indicates which CPU is related to the data. Like the first exemplary embodiment, when receiving the 4-byte data and the write request, the detecting section 21b generates the 3-byte error detection and correction code based on the 4-byte data. The detecting section 21b supplies the 4-byte data, the 3-byte error detection and correction code, the 1-byte auxiliary data and the write request to the interface section 22b.

Also, at the time of reading data, that is, when receiving the 4-byte data, the 3-byte error detection and correction code and the 1-byte auxiliary data from the interface section 22b, the detecting section 21b executes the error detection to data read from every two of the four semiconductor memories 11 based on the 3-byte error detection and correction code. When there is any error, the detecting section 21b executes the error correction to the 1-byte data of the 4-byte data. It should be noted that the detection and correction of the error are the same as those of the detecting section 21 in the first exemplary embodiment.

At the time of writing data, that is, when receiving the 4-byte data, the 3-byte error detection and correction code, the 1-byte auxiliary data and the write request from the detecting section 21b, the interface section 22b stores these data in the memory module 10 through the interface section 30. In detailed, the interface section 22 stores the 4-byte data in the four semiconductor memories 11 one byte by one byte, the 3-byte error detection and correction code in the three semiconductor memories 11 one byte by one byte, and the 1-byte auxiliary data in the auxiliary semiconductor memory 11.

Also, at the time of reading data, that is, when receiving the read request from the detecting section 21b, the interface section 22b reads the 4-byte data from the four semiconductor memories 11 one byte by one byte, the 3-byte error detection and correction codes from the three semiconductor memories 11 one byte by one byte, and the 1-byte auxiliary data from the remaining semiconductor memory 11. The interface section 22b supplies the 4-byte data, the 3-byte error detection and correction code and the 1-byte auxiliary data to the detecting section 21b.

The data write operation of the memory system 1b according to the third exemplary embodiment of the present invention will be described. Here, referring to FIG. 4, the data write operation according to the third exemplary embodiment of the present invention will be described.

### (Data Writing Operation)

### Step S01:

The external unit 2 supplies the 4-byte data, the 1-byte auxiliary data and the write request to the memory system 1 through the system interface section 3.

### Step S02:

When receiving the 4-byte data, the 1-byte auxiliary data and the write request, the detecting section 21b generates the 3-byte error detection and correction code based on the 4-byte data. The detecting section 21b supplies the 4-byte data, the 3-byte error detection and correction code, the 1-byte auxiliary data and the write request to the interface section 22b.

### Step S03:

When receiving the 4-byte data, the 3-byte error detection and correction code, the 1-byte auxiliary data and the write request from the detecting section 21b, the interface section 22b stores these data in the memory module 10 through the interface section 30. In detailed, the interface section 22b stores the 4-byte data in the four semiconductor memories 11 one byte by one byte, the 3-byte error detection and correction code in the three semiconductor memories 11 one byte by one byte, and the 1-byte auxiliary data in the remaining semiconductor memory 11.

As mentioned above, the memory system 1b according to the third exemplary embodiment of the present invention attains the same effect as the first exemplary embodiment, and the auxiliary data which is provided for the auxiliary semiconductor memory 11 from the external unit 2 can be stored. In other words, when the external unit 2 is a system which has a plurality of CPUs that share the memory module 10, the memory system 1b can store data indicative of which CPU is related to the 4-byte data in the memory module 10. As a result, the memory system 1b attains the effect of dealing with the system which has the plurality of CPUs, by using not a plurality of memory modules 10 but a single memory module 10. It should be noted that the memory module 10 in the third exemplary embodiment may have nine semiconductor memories 11, like the DIMM 110 of FIG. 1. In this case, the auxiliary data may be of 2 bytes, and 1 byte may be used for the auxiliary data and another 1 byte may be used for the corrected data.

The exemplary embodiments of the present invention have been described and can be combined in a range without contradiction.

What is claimed is:

1. A memory system comprising:
a memory module comprising first to eighth semiconductor memories of an n-bit input/output type; and
a memory control unit configured to generate three n-bit error detection and correction code based on four n-bit data received from an external system, respectively store the four n-bit data in said first to fourth semiconductor memories, and respectively store the three n-bit error detection and correction code in said fifth to seventh semiconductor memories,
wherein, when reading the four n-bit data stored in said first to fourth semiconductor memories, said memory control unit executes error detection to every two of the four n-bit data read from said first to fourth semiconductor memories based on the three n-bit error detection and correction code stored in said fifth to seventh semiconductor memories and executes error correction to one n-bit data related to an error, of the four n-bit data based on the three n-bit error detection and correction code.

2. The memory system according to claim 1, wherein, when executing the error correction to the one n-bit data related to an error, said memory control unit stores corrected data in said eighth semiconductor memory.

3. The memory system according to claim 2, wherein said memory module further comprises a ninth semiconductor memory of an n-bit input/output type,
wherein, when receiving n-bit directory data from said external system together with the four n-bit data, said memory control unit stores the n-bit directory data in said ninth semiconductor memory.

4. The memory system according to claim 1, wherein n is 4 or 8.

5. A memory module control method comprising:
writing four n-bit data received from an external system in a memory module comprising first to eighth semiconductor memories; and
reading the four n-bit data from said memory module in response to on a request from said external system,
wherein said writing comprises:
receiving the four n-bit data from said external system;
generating three n-bit error detection and correction code based on the four n-bit data;
storing the four n-bit data in said first to fourth semiconductor memories, respectively; and
storing the three n-bit error detection and correction code in said fifth to seventh semiconductor memories, respectively, and
wherein said reading comprises:
reading the four n-bit data from said first to fourth semiconductor memory in response to the request from said external system, respectively;
reading the three n-bit error detection and correction code from said fifth to seventh semiconductor memories, respectively;
executing error detection to every two of the four n-bit data read from said first to fourth semiconductor memories based on the three n-bit error detection and correction code read from said fifth to seventh semiconductor memories; and
executing error correction to one n-bit data related to an error, of the four n-bit data based on the three n-bit error detection and correction code, when the error is detected in the four n-bit data.

6. The memory module control method according to claim 5, wherein said executing error correction comprises:
storing corrected data in said eighth semiconductor memory when executing the error correction to said one semiconductor memory.

7. The memory module control method according to claim 6, wherein said writing comprises:
receiving the four n-bit data and n-bit directory data from said external system; and
storing the n-bit directory data in a ninth semiconductor memory of an n-bit input/output type in said memory module.

8. The memory module control method according to claim 5, wherein n is 4 or 8.
